(19) United States
(12) Patent Application Publication
(10) Pub. No.: US 2026/0132541 A1
(43) Pub. Date: May 14, 2026

(54) SYNTHESIS OF MONOLAYER TRANSITION METAL DICHALCOGENIDES BY ELECTROSTATIC SELF-ASSEMBLY

(71) Applicant: California Institute of Technology, Pasadena, CA (US)

(72) Inventors: Daniel Anderson, Pasadena, CA (US); Nai-Chang Yeh, Pasadena, CA (US)

(73) Assignee: California Institute of Technology, Pasadena, CA (US)

(21) Appl. No.: 18/939,211

(22) Filed: Nov. 6, 2024

Related U.S. Application Data
(60) Provisional application No. 63/547,659, filed on Nov. 7, 2023.
(60) Provisional application No. 63/683,549, filed on Aug. 15, 2024.

(51) Int. Cl. C30B 25/18; C30B 29/46

(52) U.S. Cl. CPC C30B 25/18; C30B 29/46

(57) ABSTRACT

A method of growing a transition metal dichalcogenide includes providing a substrate and positioning the substrate in a furnace. The method also includes reducing a transition metal compound to produce a plurality of reduced transition metal compounds. The plurality of reduced transition metal compounds is electrostatically aligned on the substrate. The method further includes reacting the plurality of reduced transition metal compounds with a chalcogen precursor to form one or more layers of a transition metal dichalcogenide.

### CROSS-REFERENCES TO RELATED APPLICATIONS

This application claims benefit under 35 USC§ 119(e) to U.S. Provisional Patent Application No. 63/547,659 filed Nov. 7, 2023 entitled “Synthesis Of Monolayer Transition Metal Dichalcogenides (TMDs) by Electrostatic Self-Assembly,” and U.S. Provisional Patent Application No. 63/683,549 filed Aug. 15, 2024 entitled “Synthesis Of Monolayer Transition Metal Dichalcogenides (TMDs) by Electrostatic Self-Assembly,” the disclosures of which are hereby incorporated by reference in their entirety.

### STATEMENT AS TO RIGHTS TO INVENTIONS MADE UNDER FEDERALLY SPONSORED RESEARCH AND DEVELOPMENT

This invention was made with government support under Grant No. PHY1733907 awarded by the National Science Foundation. The government has certain rights in the invention.

### BACKGROUND OF THE INVENTION

Monolayer transition metal dichalcogenides (TMDs) are a class of two-dimensional (2D) direct bandgap semiconductors with great promise as information processing materials in next generation electronics, photonics, and optoelectronics. TMDs have a chemical formula of MX₂, with M a transition metal atom (Mo, W, and the like) and X a chalcogen atom (S, Se, or Te). A monolayer lattice includes one layer of M atoms sandwiched between two layers of X atoms.

Despite the progress made in the area of TMDs, there is a need in the art for improved methods and systems related to the synthesis of TMDs.

### SUMMARY OF THE INVENTION

The present invention relates generally to methods and systems for materials synthesis. More particularly, embodiments of the present invention provide methods and systems for growing monolayer transition metal dichalcogenides (TMDs) using an electrostatic self-assembly process. Merely by way of example, the invention has been applied to a method of synthesizing transition metal dichalcogenide (TMD) monolayers suitable for industrial application, including complementary metal-oxide-semiconductor (CMOS) compatible semiconductor processes, thereby enabling implementation of these materials in next-generation semiconductor devices. The invention is applicable to a variety of growth systems, transition metals, and chalcogenides.

Numerous benefits are achieved by way of the present invention over conventional techniques. For example, embodiments of the present invention provide a method of growing large area TMD monolayers using an electrostatic self-assembly process on a substrate, including an amorphous substrate such as SiO₂, at CMOS compatible temperatures. The TMD monolayers discussed herein are characterized by fully connected grains with grain sizes on the order of millimeters, which are significantly larger than TMDs produced using conventional approaches. These and other embodiments of the disclosure, along with many of its advantages and features, are described in more detail in conjunction with the text below and corresponding figures.

### BRIEF DESCRIPTION OF THE DRAWINGS

FIGS. 1A-1F are simplified perspective schematic diagrams illustrating stages of a TMD growth process according to an embodiment of the present invention.

FIG. 2 is an optical micrograph of the aligned, reduced transition metal compound according to an embodiment of the present invention.

FIG. 3A is an optical micrograph of aligned domains of the reduced transition metal compound according to an embodiment of the present invention.

FIG. 3B is an optical micrograph of MoCl₅ deposited under the same conditions as in FIG. 3A without the flux of Cs.

FIG. 4A is a scanning electron micrograph of monolayer MoS₂ crystallites aligned on an amorphous SiO₂ substrate according to an embodiment of the present invention.

FIG. 4B is a scanning electron micrograph of the monolayer MoS₂ crystallites aligned on an amorphous SiO₂ substrate illustrated in FIG. 4A at a higher resolution.

FIG. 5A is an optical microscope image of MoS₂ grown at a centimeter scale using CsI as the unbalanced reductant according to an embodiment of the present invention.

FIG. 5B is a photoluminescence map of the MoS₂ shown in FIG. 5A according to an embodiment of the present invention. The excitation laser wavelength for the photoluminescence measurement is 514 nm.

FIG. 5C is a map of the wavenumber difference between the two resonant Raman modes (peaks A_{1g} and E_{2g}) in the MoS₂ Raman spectrum for the MoS₂ shown in FIG. 5A according to an embodiment of the present invention. The excitation laser wavelength for the Raman spectroscopic measurements is 514 nm.

FIG. 5D is a map of the degree of valley polarization (DOV) at room temperature for the MoS₂ shown in FIG. 5A according to an embodiment of the present invention.

FIG. 6 is a simplified schematic diagram of a CVD system employed to synthesize 2D-TMD materials by electrostatic self-assembly according to an embodiment of the present invention.

FIG. 7 is a simplified flowchart of a method of growing 2D-TMD materials by CVD according to an embodiment of the present invention.

FIG. 8A is an optical microscopy image of CVD-grown MoS₂ on a sapphire substrate with the addition of CsI according to an embodiment of the present invention.

FIG. 8B is a second optical microscopy image of the CVD-grown MoS₂ shown in FIG. 8A indicating a monolayer region of interest according to an embodiment of the present invention.

FIG. 8C is a photoluminescence map of the monolayer region of interest highlighted in FIG. 8B.

FIG. 8D is a map of the wavenumber difference between the two resonant Raman modes (peaks A_{1g} and E_{2g}) in the MoS₂ Raman spectrum for the monolayer region of interest highlighted in FIG. 8B.

FIG. 9 is a simplified schematic diagram illustrating an MOCVD system for synthesis of 2D-TMD materials by electrostatic self-assembly according to an embodiment of the present invention.

FIG. 10 is a simplified flowchart illustrating a method of growing a monolayer TMD by MOCVD according to an embodiment of the present invention.

FIG. 11A is an optical microscopy image of MOCVD-grown MoS₂ on a SiO₂ substrate with the addition of cesium metal according to an embodiment of the present invention.

FIG. 11B is an optical microscope image of the MOCVD-grown MoS₂ shown in FIG. 11A at a second, higher magnification according to an embodiment of the present invention.

FIG. 11C is a photoluminescence intensity map of the region contained in the dashed box shown in FIG. 11B according to an embodiment of the present invention.

FIG. 11D is a map of the wavenumber difference between the two resonant Raman modes (peaks A_{1g} and E_{2g}) in the MoS₂ Raman spectrum for the region contained in the dashed box shown in FIG. 11B according to an embodiment of the present invention.

FIG. 12 is a simplified schematic diagram illustrating an alternative MOCVD system for synthesis of 2D-TMD materials by electrostatic self-assembly according to an embodiment of the present invention.

### DETAILED DESCRIPTION OF SPECIFIC EMBODIMENTS

The present invention relates generally to methods and systems related to materials synthesis. More particularly, embodiments of the present invention provide methods and systems for growing monolayer transition metal dichalcogenides using an electrostatic self-assembly process. Merely by way of example, the invention has been applied to a method of synthesizing transition metal dichalcogenide monolayers suitable for industrial application, including CMOS compatible semiconductor processes, thereby enabling implementation of these materials in next-generation semiconductor devices. The invention is applicable to a variety of growth systems, transition metals, and chalcogenides.

Present production methods for monolayer TMDs are prohibitive to the practical implementation of these materials in the semiconductor industry, since they do not satisfy, in full, the industry requirements of scalability, high crystallinity, direct temperature compatibility with CMOS electronics (the upper limit for back-end-of-line processes being 450° C.), high mobility, and cost effectiveness. Previous work to ameliorate synthetic difficulties have fallen short. Some schemes trade scalability and temperature compatibility for improvements in crystallinity and mobility, whereas others have sacrificed mobility and crystallinity for scalability and temperature compatibility. To manifest a deterministic process that satisfies a range of industrial constraints has hitherto proven to be elusive.

Embodiments of the present invention provide methods and systems for the synthesis and chemical vapor deposition (CVD) of TMD materials in which a reductant is added to electrostatically unbalance the transition metal precursor (e.g., salts and transition metal complexes containing elements such as Mo and W), thereby inducing Coulombic order among the reduced transition metal precursor material on the surface of a semiconducting (such as silicon, GaAs, GaP, GaInAs, or GaInP) or insulating (such as SiO₂, SiC, sapphire, glass, HfO₂, or the like) synthesis substrate and reducing the barrier to monolayer formation. Subsequently, a chalcogen precursor acting as a co-reactant (such as S, Se and Te) is introduced to produce 2D-TMD material and remove excess charge from the product.

The inventors have determined that by adding an auxiliary reductant such as iodide, bromide, hydroxide, borohydride, or pivalate charge compensated by a “noble” ion, such as cesium, lithium, ammonium, rubidium, or quaternary ammonium, to a molybdenum or tungsten precursor with valence state V and/or VI, it is possible to produce a reduced reaction intermediate of molybdenum or tungsten with valence state IV and/or V, which is charge compensated by the “noble” ion (i.e., one that interacts poorly with the charge held by the reduced transition metal precursor, also referred to as a reduced transition metal compound or a reduced intermediate). As an example, the reaction to produce the unbalanced transition metal precursor proceeds as follows in the cesium iodide-molybdenum trioxide system beginning at 500° C.:

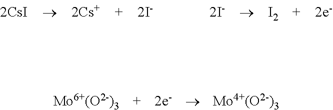

### Overall,

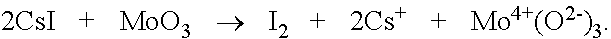

Notably, since iodine is a gas at this reaction temperature, it is swiftly evacuated from the system by an argon gas stream and, in turn, does not interact with the system. In addition, the oxide of cesium (Cs₂O), the formation of which is a conceivable process, is the strongest known base and cannot stably form at high temperatures to balance the charge of the reduced molybdenum precursor Mo⁴⁺(O²⁻)₃. Accordingly, the charged precursor can be retained on the substrate without further oxidation or chemothermal decomposition.

By adding an auxiliary reductant such as cesium, lithium, rubidium, silver, or magnesium, the same reaction intermediates can be produced without the use of an anion (halide or otherwise) or temperatures higher than standard atmospheric temperature. Considering the cesium metal-molybdenum trioxide system, the following reaction is spontaneous at room temperature:

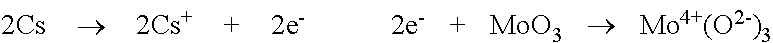

### Overall,

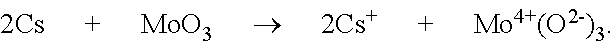

By using an electron beam, high electric fields, or a gated substrate, as well as a transition metal precursor, it is possible to produce the same reduced intermediate without the use of a counterion, as exemplified below if we consider the system of molybdenum trioxide:

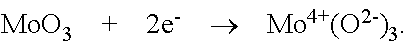

Using this process enables chemical impurities, which may be otherwise introduced, to be reduced or eliminated. Moreover, since the growth process is temperature dependent, removing the auxiliary reductant (e.g., an alkali metal such as cesium) from the reaction eliminates the temperature dependence of the process since the chemical reductant, acting as a charge compensator to the reduced transition metal compound, otherwise produces a parasitic Coulombic interaction. In a specific embodiment, the absence of the metal reductant will eliminate this Coulombic interaction and result in a temperature independent growth process.

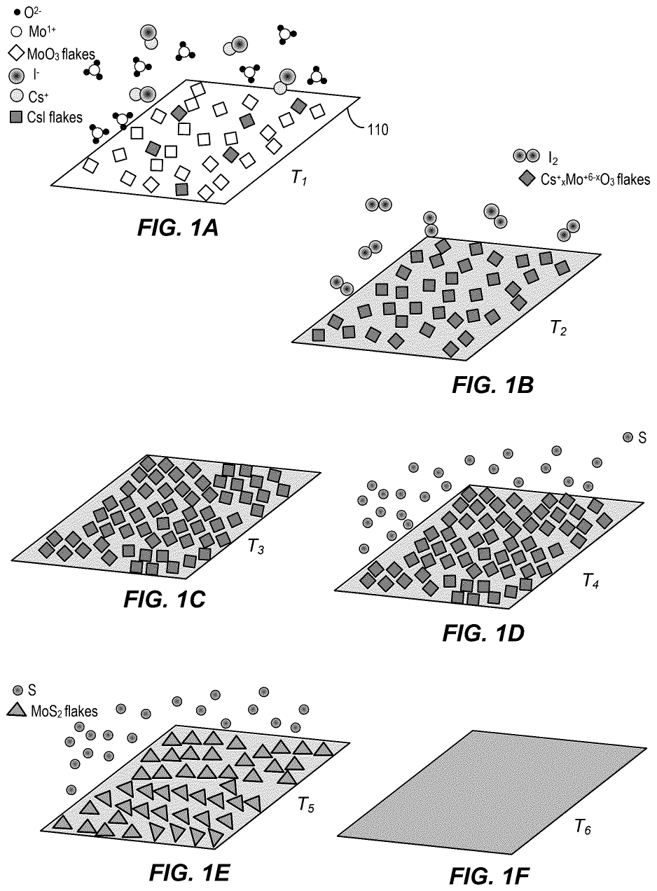

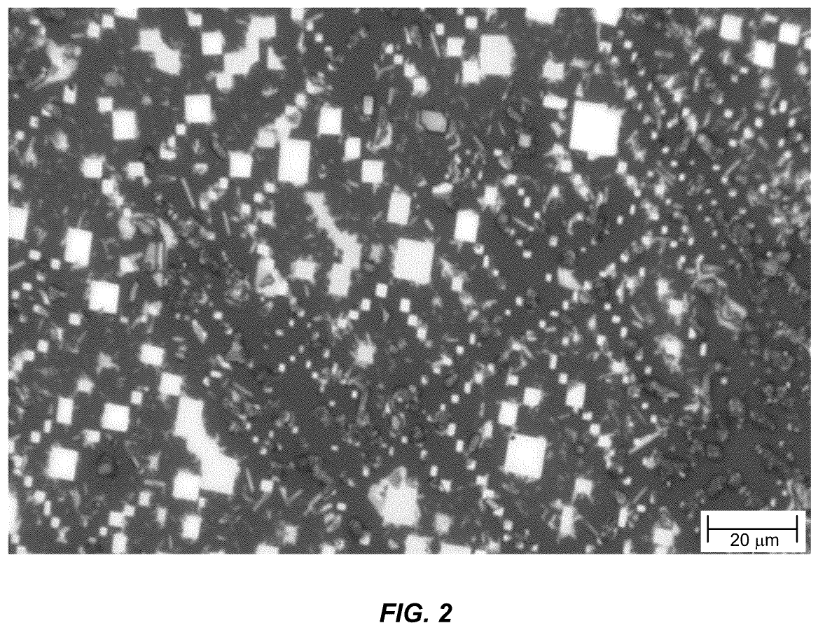

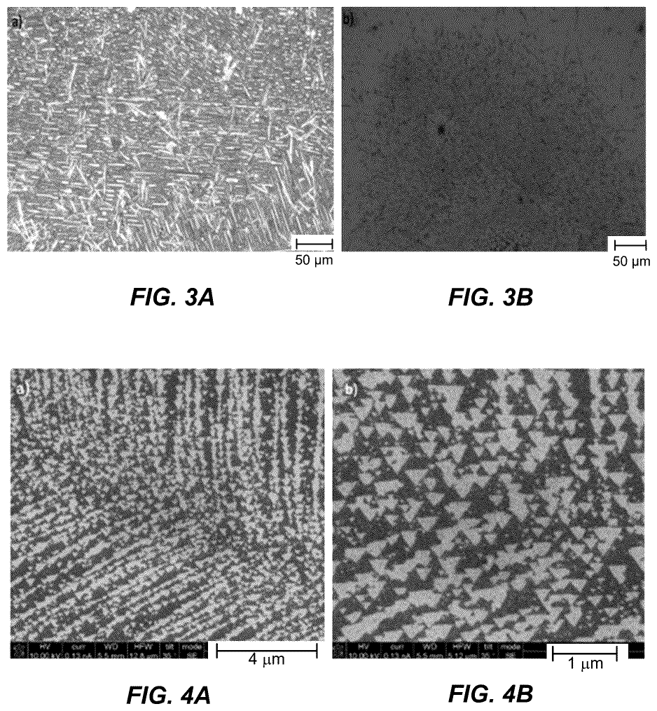

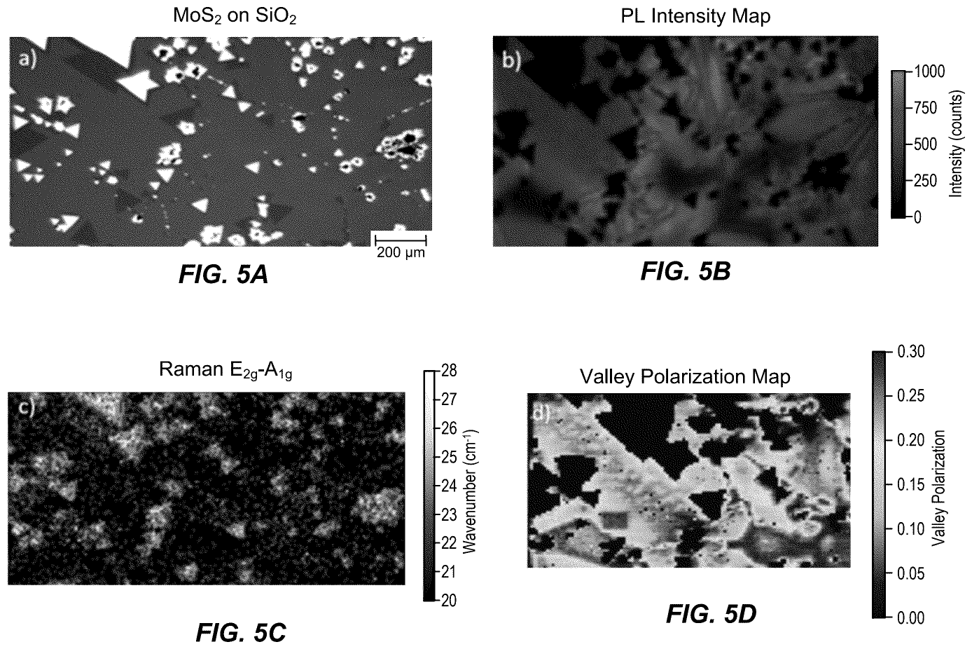

As illustrated in FIGS. 1A-1D, at sufficiently high temperatures unique to each system of reductant and transition metal precursor, the reduced transition metal compound, also referred to as a charged precursor, flux condenses on the synthesis substrate and electrostatically orders into aligned crystallites. For example, CVD alignment of CsI—MoO₃ and MOCVD alignment of Cs—MoCl₅ are illustrated in the micrographs shown in FIGS. 2 and 3A, respectively. At the reaction temperature, a vapor stream of sulfur, selenium, or tellurium converts the array of precursor crystallites to flakes of the 2D-TMD retaining the geometric order of the precursor as illustrated by the scanning electron micrograph shown in FIGS. 4A and 4B. With continuous chalcogen flux, the monolayers grow commensurate with each other, producing high-quality, mm-size connected single crystal domains at a wafer scale as shown in FIG. 5A, which affords a post-synthesis picture of a TMD sample: a connected, wafer-scale monolayer with mm-size grains as well as some small, multilayer TMD crystals.

By reducing the transition metal precursor, the conversion to the product proceeds at a higher rate, since the reduction to the IV oxidation state occurs prior to the introduction of the chalcogen, reducing the energy barrier for the reaction.

Insomuch that the system proceeds by negative charge alignment, the system will avoid forming negatively charged chalcogen defects as in conventional CVD processes without the precursors. Instead, the system will form fewer highly positively charged metal defects. The net effect is a TMD with lower defect densities than those obtained with alternative processes, as evidenced by the degree of valley polarization (DOV) map in FIG. 5D, which features significantly higher average DOV at 300 K (17%) than those corresponding to conventional processes. Here the DOV is defined as follows:

$$DOV ≡ \vert [ I ( σ + ) - I ( σ - ) ] / [ I ( σ + ) + I ( σ - ) ] \vert ,$$

where I(σ_{±}) represents the photoluminescence intensity of the TMD at the A-exciton energy taken under right handed (left handed) circularly polarized light σ₊ (σ₋). It should be noted that the DOV in semiconducting monolayer TMDs is a standard measure of the quality of the TMDs. For an ideal system at absolute zero temperature, with no intervalley scattering due to imperfections or phonons, the theoretical value of the DOV would be 100% due to the strong spin-valley coupling in monolayer TMDs. In all semiconducting monolayer TMDs reported to date, however, the DOV of the as-grown samples at room temperature is typically very low (<˜5%) due to defects (such as vacancies and grain boundaries) and strong phonon scattering effects.

Grain sizes can be increased with slower temperature ramp up times, since this affords the reduced transition metal compound, also referred to as a charged precursor, more time to align on the substrate before conversion to TMD.

Given that the nature of the synthesis reaction is dominated by a substrate-independent mechanism so long as the substrate is not highly conducting, (i.e., the electron affinity of the substrate plus the latent thermal energy is sufficiently smaller than the work function of the charged precursor so that the charge transfer rate from the charged precursor to the substrate is slow during the synthesis process) the synthetic process shares common features for insulating and/or amorphous substrates including silicon dioxide, silicon (including single crystalline silicon), sapphire (including single crystalline sapphire), silica, and other 2D semiconducting or insulating materials.

The self-assembly process and synthetic principles can hold at temperatures compatible with those for processing CMOS electronics, i.e., processes performed at less than or equal to 450° C. As an example, the temperature of the furnace while the plurality of reduced transition metal compounds is condensed onto the substrate surface can be less than 450° C. Moreover, the temperature of the furnace while the plurality of reduced transition metal compounds is converted to one or more layers of a transition metal dichalcogenide can be less than 450° C.

The precursor materials used for the synthesis are inexpensive and readily available.

External impetuses such as an in-plane electric field or a gated substrate may be used to improve precursor alignment and produce a larger-grained sample.

The procedure for electrostatic self-assembly applies to all CVD processes, namely conventional CVD and metal-organic chemical vapor deposition (MOCVD).

Inasmuch as metal carbonyls and other stabilized transition metal complexes (such as Mo(CO)₆ and W(CO)₆, which are frequently employed as precursors in MOCVD) can accommodate negative charge donated from alkali metals, in spite of the fact that the metal centers have an oxidation state of zero, these materials may also be employed as precursors for electrostatic self-assembly.

FIGS. 1A-1F are simplified perspective schematic diagrams illustrating stages of a TMD growth process according to an embodiment of the present invention. The TMD growth process illustrated in these figures produces large-grained monolayer TMDs at a wafer scale. Referring to FIG. 1A, which uses the CsI—MoO₃ system as an example, a simplified schematic diagram is provided that illustrates an unbalanced transition metal precursor, which could be a monolayer, for example, (Cs⁺)₂ Mo⁴⁺(O²⁻)₃, that Coulombically aligns on the substrate surface due to poor compensation by its conjugate cation. In this first step at a temperature T₁ where the transition metal precursor materials attain a sufficient vapor pressure, the precursor materials condense onto the substrate surface. Accordingly, as illustrated in FIG. 1A, MoO₃ and CsI vapor condenses onto the substrate 110, which in this embodiment, is a SiO₂ substrate.

As illustrated in FIG. 1B, upon reaching a temperature T₂ where T₂>T₁, the MoO₃ reacts with the CsI reductant, forming the reduced transition metal compound (i.e., the reduced intermediate, e.g., Cs^{+x}Mo^{+6-x}(O²⁻)₃ in the nonideal, nonstoichiometric case). Thus, the reduction of MoO₃ to form the reduced intermediate by the CsI reductant is illustrated in FIG. 1B. The Cs^{+x}Mo^{+6-x}(O²⁻)₃ flakes are illustrated as present on the substrate surface, but not aligned with respect to each other. As a result, the orientation of the flakes is substantially random at this stage of the growth process. It should be noted that embodiments of the present invention include chemical reactions that add electrons to the transition metal precursor and hence reduce the oxidation state of the transition metal cation present.

Referring to FIG. 1C, as the furnace (e.g., now at a temperature T₃ where T₃>T₂) continues to heat to the reaction temperature, ordered domains form apace as a consequence of a greater intermediate flux and the unbalanced Coulombic surface potential issuing from the poor compensation of the reduced intermediate by the conjugate cesium ion. As shown in FIG. 1D, further self-assembly of the crystallites due to electrostatic alignment occurs as the temperature increases (e.g., to T₄ where T₄>T₃) and the chalcogenide precursor (sulfur in this example) is introduced. The inventors believe, without limiting embodiments of the present invention, that a charge imbalance is present at the substate surface. In order to reduce the effect of the charge imbalance, the reduced intermediate electrostatically align on the surface as shown in FIG. 1D in order to minimize the energy of the system.

Referring to FIG. 1E, at the reaction temperature of T₅ where T₅>T₄, gaseous sulfur present in the system, converts the aligned, monolayer reduced intermediate to an aligned, monolayer TMD. In an exemplary embodiment, the reaction of the sulfur with the reduced intermediate (Cs^{+x}Mo^{+4-x}O₃ in the general case) results in the formation of aligned, monolayer MoS₂ as shown in FIG. 1E, where the spectator Cs reacts with the excess of sulfur or evolved oxygen to form sulfide and oxide vapors that leave the system with the carrier gas at temperature T₅.

Ultimately, as shown in FIG. 1F, which illustrates a substrate covered by a monolayer TMD (e.g., MoS₂), the TMD flakes coalesce to large single crystals with domain sizes approaching the millimeter scale, and, as this process happens over the entirety of the substrate, these larger crystals maintain alignment to grow to a wafer scale. In some embodiments, the temperature at this stage of the growth process is T₅ and the TMD flakes coalesce to larger single crystals without grain boundaries due to the alignment. The TMD is characterized as a 2D structure since its thickness d ranges from only a monolayer (<0.1 nm) to a few monolayers (e.g., two or three monolayers) whereas its lateral dimension L (≥1 mm) is many orders of magnitude larger than d and its optical properties (e.g., the peak positions of the Raman modes) are distinct from those of the bulk material.

FIGS. 1A-1F illustrate an exemplary growth process that occurs at temperatures from T₁ to T₅ (where T₁<T₂<T₃<T₄<T₅) without specifying the exact temperatures because these reaction temperatures depend on the precursor materials. For the reduction of MoO₃ by CsI and the reaction of the aligned MoO₃ flakes with S in a CVD process, we find that T₁˜500° C., T₂˜600° C., T₃˜675° C., T₄˜785° C., and T₅˜800° C. On the other hand, one can utilize other materials and the corresponding reaction temperatures. In other embodiments, including MOCVD processes, the temperature of the furnace can be less than 450° C. (e.g., 350° C.) while the plurality of reduced transition metal compounds is condensed onto the substrate surface. Moreover, the temperature of the furnace while the plurality of reduced transition metal compounds is converted to one or more layers of a transition metal dichalcogenide can be less than 450° C. One of ordinary skill in the art would recognize many variations, modifications, and alternatives.

Moreover, although the growth process illustrated in FIGS. 1A-1F utilized MoO₃ as the transition metal precursor, CsI as the reductant gas, S as the chalcogen precursor, and MoS₂ as the TMD, this is merely exemplary and, as discussed more fully below, a variety of different transition metal precursors, reductants, and chalcogen precursors can be utilized to produce the electrostatically aligned intermediates that are able to hold charge during the self-assembly process and eventually react with the chalcogen precursor to produce the final TMD. Accordingly, the use of CsI as an alkali metal-halogen compound is merely exemplary and other alkali metals and halogens can be utilized.

FIG. 2 is an optical micrograph of the aligned, reduced transition metal compound according to an embodiment of the present invention. The aligned transition metal compound is a CsI—MoO₃ intermediate in the example illustrated in FIG. 2 and was produced using CVD on an SiO₂ substrate by heating the precursors in the furnace without the addition of a chalcogen precursor. The distinct color of each crystallite is determined by its thickness on the substrate, where the thickest crystallites appear opaque and white, the thinner crystallites appear dark blue, and the thinnest are translucid and assume the blue color of the SiO₂. As shown in FIG. 2, the aligned, reduced transition metal compound, which can also be referred to as a reduced intermediate, illustrated schematically in FIG. 1C electrostatically aligns on the substrate surface. In order to image these aligned, reduced intermediate structures, the synthesis was reproduced without the addition of the chalcogen to capture the intermediate stage of the growth process and illustrate the alignment of the reduced intermediate.

FIG. 3A is an optical micrograph of aligned domains of the reduced transition metal compound according to an embodiment of the present invention. The reduced transition metal compound is a Cs—MoCl₅ intermediate in the example illustrated in FIG. 3A and was produced using MOCVD on a SiO₂ substrate by heating the precursors in the furnace for 24 hours without the addition of a chalcogen precursor. Optical contrast is once again determined by the thickness of deposited compound, appearing a given color when the thickness satisfies the local diffraction condition.

FIG. 3B is an optical micrograph of MoCl₅ deposited under the same conditions as in FIG. 3A without the flux of Cs.

Comparing FIGS. 3A and 3B, the self-assembly process shown in FIG. 3A is absent in FIG. 3B, the latter is a process performed without the presence of the reductant Cs to reduce the transition metal compound (e.g., MoO₃) into the unbalanced, monolayer reduced intermediate, for example, Mo⁴⁺(O²⁻)₃, that can Coulombically align on the substrate surface due to poor compensation by the conjugate Cs cation. As a result, since the electrostatic alignment resulting from the unbalanced Coulombic surface potential is absent in the absence of the conjugate cation, the orientation of the reduced intermediate is random and no self-assembly occurs as shown in FIG. 3B. This result is similar to what is achieved in some conventional CVD processes that produce isolated TMD samples that do not connect to cover the entire surface of the substrate. Additionally, these conventional processes produce TMDs that are often multiple layers thick, not uniformly monolayer.

FIG. 4A is a scanning electron micrograph of monolayer MoS₂ crystallites aligned on an amorphous SiO₂ substrate according to an embodiment of the present invention. In FIG. 4A, the scalebar is 4 m and the figure provides experimental evidence for alignment of the monolayer reduced intermediate during the intermediate growth process. The black triangles are individual crystallites, which align and grow to larger single crystal grains according to the process discussed in relation to FIGS. 1A-1F. The substrate appears as the gray background in the scanning electron micrograph. It should be noted that the synthesis time was deliberately shortened (i.e., from a typical growth time of 10 minutes to a growth time of 2 minutes) to capture the intermediate stage of the growth process and reduced intermediate alignment. Thus, FIG. 4A provides experimental evidence for alignment of monolayer precursors during the intermediate growth process. Further growth results in the monolayer TMD illustrated, for example in FIG. 5A.

FIG. 4B is a scanning electron micrograph of the monolayer MoS₂ crystallites aligned on an amorphous SiO₂ substrate illustrated in FIG. 4A at a higher resolution. In FIG. 4B, the scalebar is 1 m. Embodiments of the present invention are able to utilize a wide variety of substrates, including amorphous substrates such as SiO₂, and glass, as well as crystalline substrates such as sapphire and semiconducting TMDs. In particular, embodiments of the present invention are able to grow TMD monolayers on amorphous substrates despite the fact that amorphous substrates, by nature, have no periodic lattice structure and, as a result, do not have a surface potential that can break rotational symmetry and create alignment of adhered compounds. In addition to the surface morphology of the substrate, e.g., amorphous or crystalline, the electrical properties of the substrate can also vary. As an example, both electrically insulating substrate such as SiO₂ and sapphire, as well as semiconducting substrates such as Si and semiconducting TMDs, can be utilized according to embodiments of the present invention.

FIG. 5A is an optical microscope image of MoS₂ grown at a centimeter scale using CsI as the unbalanced reductant according to an embodiment of the present invention. In FIG. 5A, the scalebar is 200 μm. The translucent, semidiaphanous background is monolayer MoS₂, whereas the white and darker regions are bulk and multilayer MoS₂, respectively. The substrate used during this growth process was a SiO₂ substrate. The maximum grain size for the monolayer MoS₂ appearing as the background reaches a scale greater than 1 mm, and the bulk areas serve as the bellwether for alignment since it maintains the local alignment and has excellent optical contrast with the substrate. Thus, FIG. 5A provides experimental evidence for fully connected wafer-scale monolayer MoS₂ with mm-size grains.

FIG. 5B is a photoluminescence map of the MoS₂ shown in FIG. 5A according to an embodiment of the present invention. Since monolayer MoS₂ is a direct bandgap semiconductor with a bandgap energy of ˜1.9 eV, excitation with a laser above the bandgap energy will result in light emission at the red wavelength. Here the wavelength of the excitation laser is 514 nm, which corresponds to a photon energy of 2.41 eV. On the contrary, the bulk and multilayer regions, as well as the SiO₂ substrate, are indirect bandgap semiconductors with order-of-magnitude suppressed photoluminescence intensity at different wavelengths, which is why these regions appear black in the image. Thus, consistent with the optical microscope image shown in FIG. 5A, monolayer MoS₂ is present across the entire substrate, with some regions of multilayer MoS₂ formed on top of the monolayer MoS₂ covering the substrate.

FIG. 5C is a map of the wavenumber difference between the two resonant Raman modes (spectral peaks associated with the A_{1g} and E_{2g} modes) in the MoS₂ Raman spectrum for the MoS₂ shown in FIG. 5A according to an embodiment of the present invention. Monolayer MoS₂ tends to exhibit a wavenumber difference in the A_{1g} and E_{2g} peaks of 19-21 cm⁻¹ while multilayer and bulk regions the wavenumber difference shifts to higher values of 22-27 cm⁻¹. Comparing FIGS. 5B and 5C, the correlation between the monolayer MoS₂ shown by high photoluminescence intensity in FIG. 5B and a low difference in wavenumber in FIG. 5C is evident. In particular, this inverse relationship between photoluminescence intensity in FIG. 5B and wavenumber difference in FIG. 5C is clear for the bulk and multilayer regions that have a low intensity (i.e., dark) in FIG. 5B and are characterized by large wavenumbers in FIG. 5C.

FIG. 5D is a map of the degree of valley polarization (DOV) at room temperature for the MoS₂ shown in FIG. 5A according to an embodiment of the present invention. The DOV is often used as an indicator of the quality of a monolayer sample, inasmuch as higher quality monolayer samples will have higher DOV by dint of the lower defect densities in these samples. While an average DOV at room temperature of 17%, as in this sample, is uncommon relative to typically <˜5% DOV in most as-grown monolayer TMDs, it is even more uncommon to attain values as large as ˜30% found in some areas of this sample, which indicates the high quality of synthesized monolayer MoS₂ produced by embodiments of the present invention. In a manner similar to that provided by a comparison of FIGS. 5B and 5C, the correlation between the monolayer MoS₂ shown by low valley polarization in FIG. 5D and high intensity in FIG. 5B and low wavenumbers in FIG. 5C is evident. In particular, this inverse relationship between valley polarization in FIG. 5C, intensity in FIG. 5B, and wavenumber in FIG. 5C is clear for the bulk and multilayer regions that are characterized by low valley polarization in FIG. 5D, have a low intensity (i.e., dark) in FIG. 5B, and are characterized by large wavenumbers in FIG. 5C.

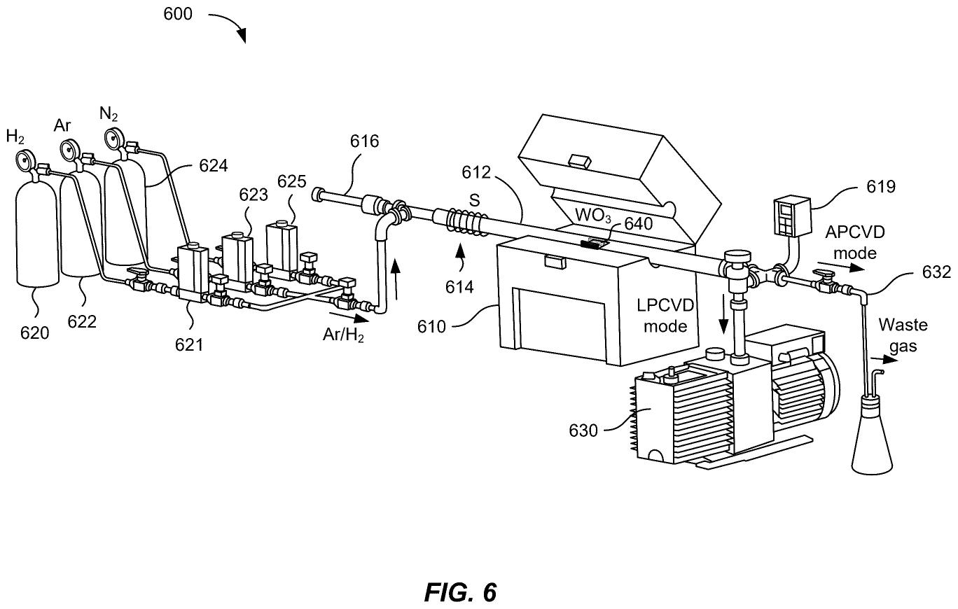

FIG. 6 is a simplified schematic diagram of a CVD system employed to synthesize 2D-TMD materials by electrostatic self-assembly according to an embodiment of the present invention. The CVD system 600 illustrated in FIG. 6 can be utilized to implement a number of the synthetic protocols delineated below. Referring to FIG. 6, growth processes are performed in a furnace 610 (e.g., a Lindberg Blue M tube furnace) using a quartz tube 612 of 1-inch radius and a length of 1 meter. Carrier gases and gaseous reagents are provided from first gas source 620, second gas source 622, and third gas source 624. In the illustrated embodiment, first gas source 620 is a hydrogen source, second gas source 622 is an argon source, and third gas source 624 is a nitrogen source. In other embodiments, the number of gas sources and the gases provided by each of the gas sources can be different as appropriate to the particular CVD growth process being performed. The gases provided by the gas sources are piped to the furnace 610 (i.e., the reaction system) with flow rates controlled by first mass flow controller 621, second mass flow controller 623, and third mass flow controller 625, which are positioned upstream of the furnace 610 and evacuated through a rotary vein pump 630 in low pressure chemical vapor deposition (LPCVD) mode or a waste gas line 632 in atmospheric pressure chemical vapor deposition (APCVD) mode.

A transition metal precursor 640 (WO₃ in the schematic) is placed in the dell of a ceramic boat within the furnace 610, upon which an ˜1 cm² substrate is suspended and heated to the reaction temperature. A chalcogenide precursor, illustrated by sulfur, is set in a boat upstream of the area circumscribed by the furnace in a low-temperature zone controlled by a secondary heating source 614. A linear positioner 616 is utilized to position the substrate in the reaction chamber. In the embodiment illustrated in FIG. 6, a pressure sensor 619 can be connected to a controller for use during the growth process.

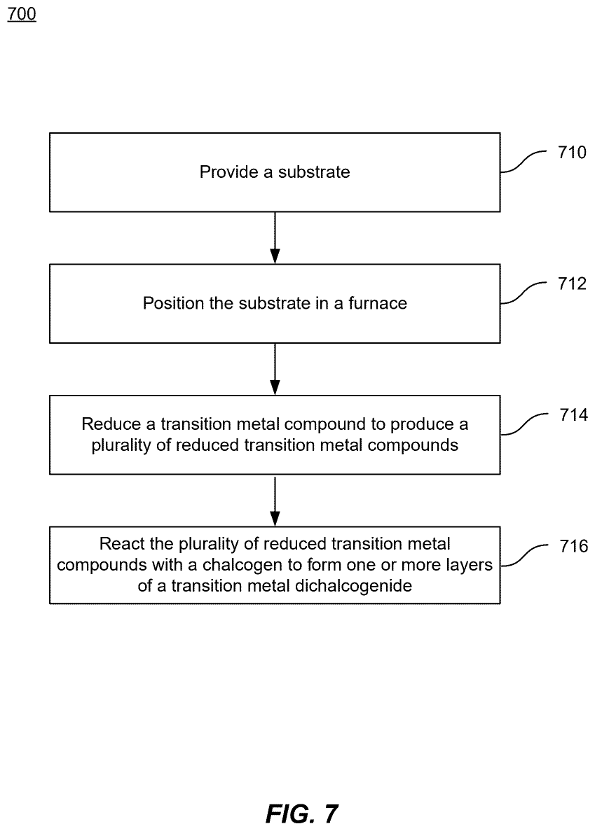

FIG. 7 is a simplified flowchart of a method of growing 2D-TMD materials by CVD according to an embodiment of the present invention. The method 700 includes providing a substrate (710) and positioning the substrate in a furnace (712). In some embodiments, the substrate is a sapphire substrate, although this is not required. Other substrates, including a silicon substrate, a silicon oxide substrate, or the like can be utilized.

The method 700 also includes reducing a transition metal compound to produce a plurality of reduced transition metal compounds (714). The plurality of reduced transition metal compounds is electrostatically aligned on the substrate. As an example, 15 mg of MoO₃ can be admixed with 15 mg of CsI and the powder couched beneath a suspended substrate in a ceramic boat to produce Cs^{+x}Mo^{+6-x}O₃ as an example of the reduced transition metal compound.

The method 700 further includes reacting the plurality of reduced transition metal compounds with a chalcogen precursor to form one or more layers of a transition metal dichalcogenide (716). Following with the example above, in a separate boat upstream (e.g., 15 inches upstream) from the substrate, 150 mg of sulfur is heated in a low temperature region and introduced into the furnace.

After evacuating the system to 30 mTorr, the quartz tube is brought back to atmospheric pressure with an argon flux of 80 sccm, whereupon the furnace is heated to ˜785° C. in 35 minutes and kept at this temperature for 10 minutes. Simultaneously, the sulfur source is heated to ˜200° C., for example, with heating tape. The Cs^{+x}Mo^{+6-x}O₃ discussed above reacts with the sulfur to form MoS₂ with cesium, sulfur, and oxygen compounds as reaction byproducts. After 10 minutes the furnace is cooled to ˜400° C. without quenching, whereupon the ceramic boat and substrate are removed from the furnace and allowed to equilibrate to atmospheric conditions. Here the empirical parameters (temperature, flow rates, etc.) are unique for the CVD growth system specified, and may be adjusted and optimized depending on variations in different components of the CVD growth system.

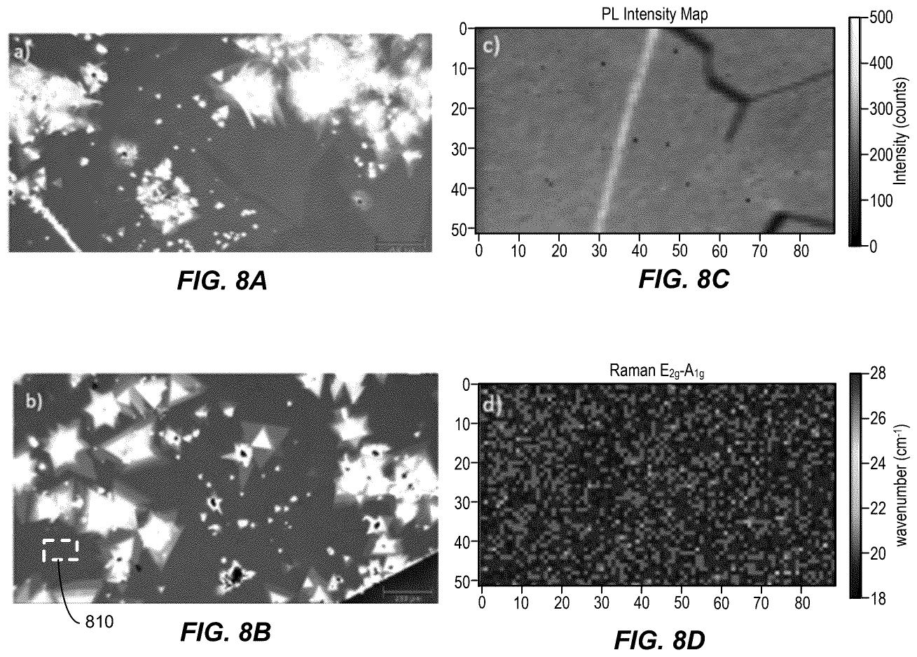

The optical and spectroscopic characteristics of the TMD material produced using method 700 are illustrated in FIGS. 8A-8D.

It should be appreciated that the specific steps illustrated in FIG. 7 provide a particular method of growing 2D-TMD materials by CVD according to an embodiment of the present invention. Other sequences of steps may also be performed according to alternative embodiments. For example, alternative embodiments of the present invention may perform the steps outlined above in a different order. Moreover, the individual steps illustrated in FIG. 7 may include multiple sub-steps that may be performed in various sequences as appropriate to the individual step. Furthermore, additional steps may be added or removed depending on the particular applications. One of ordinary skill in the art would recognize many variations, modifications, and alternatives.

FIG. 8A is an optical microscopy image of CVD-grown MoS₂ on a sapphire substrate with the addition of CsI according to an embodiment of the present invention. In accordance with the proposed mechanism of electron transfer and weak compensation, the alignment process is independent of the underlying substrate and produces comparable results, namely, single crystal sizes on the order of 1 mm, across a broad range of substrates. In FIG. 8A, the translucent background is monolayer MoS₂, whereas the white and darker regions are bulk and multilayer MoS₂, respectively. As discussed in relation to FIG. 5A, the bulk areas serve as the bellwether for alignment since it maintains the local alignment and has excellent optical contrast with the substrate. Thus, FIG. 8A provides experimental evidence for fully connected wafer-scale monolayer MoS₂ with mm-size grains.

FIG. 8B is a second optical microscopy image of the CVD-grown MoS₂ shown in FIG. 8A indicating a monolayer region of interest 810 according to an embodiment of the present invention. The analysis data collected using the monolayer region of interest 810 highlighted in the lower left corner of this optical microscopy image is discussed in relation to FIGS. 8C and 8D.

FIG. 8C is a photoluminescence map of the monolayer region of interest highlighted in FIG. 8B. Since monolayer MoS₂ is a direct bandgap semiconductor with a bandgap of ˜1.9 eV, excitation with a laser of photon energies above the bandgap energy will result in light emission at the red wavelength. As illustrated in FIG. 8C, since the entire region of interest 810 highlighted in the lower left corner of the optical microscopy image in FIG. 8B is monolayer, the photoluminescence map taken with an excitation laser wavelength of 514 nm (which corresponds to an excitation photon energy of 2.41 eV) is characterized by a substantially uniform intensity across the map.

FIG. 8D is a map of the wavenumber difference between the spectral peaks associated with two resonant Raman modes (A_{1g} and E_{2g}) in the MoS₂ Raman spectrum for the monolayer region of interest 810 highlighted in FIG. 8B. The Raman spectrum for this monolayer of MoS₂ is substantially uniform across the map, confirming the monolayer nature of the MoS₂.

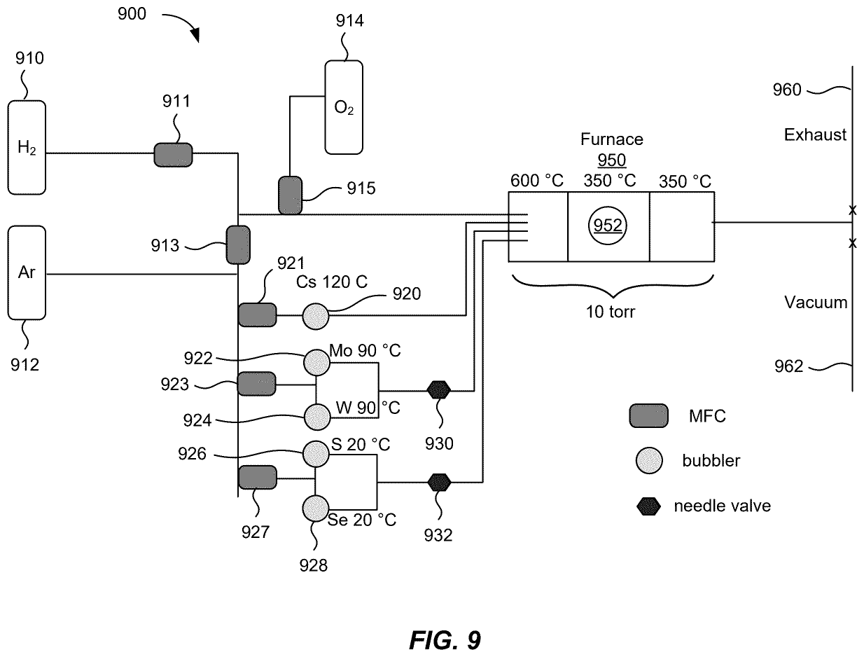

FIG. 9 is a simplified schematic diagram illustrating an MOCVD system 900 for synthesis of 2D-TMD materials by electrostatic self-assembly according to an embodiment of the present invention. Similar to FIG. 6, growth processes are performed in a furnace 950 (e.g., a Lindberg Blue M three zone tube furnace, also referred to as a reaction chamber) using a quartz tube (not shown) of 2-inch radius and a length of 1.5 meters. Argon carrier gas provided from gas source 912 and flowing through mass flow controller 913 is piped to the furnace 950. The gas flow rate is thus controlled using mass flow controller 913 upstream of external bubblers and evacuated through a rotary vein pump 962. Additionally, hydrogen gas is provided from gas source 910 and oxygen gas is provided from gas source 914. Hydrogen gas flows through mass flow controller 911 and oxygen gas flows through mass flow controller 915 before being piped to the furnace 950. Exhaust is removed using an exhaust pump 960.

Transition metal precursors (e.g., MoCl₅, MoOCl₄, MoO₂Cl₂, Mo(CO)₆, Bis(t-butylimido)bis(dimethylamino)molybdenum, Bis(t-butylimido)bis(dimethylamino)tungsten WCl₅, W(CO)₆, WOCl₄, WO₂Cl₂), chalcogen precursors (e.g. H₂S or H₂Se or H₂Te) organochalcogen precursors (e.g., diethyl sulfide, dimethyl sulfide, dimethyl selenide, diethyl selenide, dibenzyl selenide, dimethyl telluride, diethyl telluride), and cesium metal are enclosed in bubblers: bubbler 922 for Mo, bubbler 924 for W, bubbler 926 for S, and bubbler 928 for Se or Te. The pressure in the bubblers for the transition metal precursor and the organochalcogen precursor can be maintained at 750 torr by a mass flow controller and a needle valve in series. This arrangement is illustrated in FIG. 9 by mass flow controller 923 and needle valve 930 for Mo and W and mass flow controller 927 and needle valve 932 for S and Se. Temperatures of the bubblers and carrier gas flow rates can be adjusted as needed depending on the precursor and growth conditions.

The pressure in the bubbler 920 for cesium can be maintained at the pressure of the reaction chamber (i.e., the furnace) or be regulated. Flow of cesium is controlled using mass flow controller 921. In some embodiments, high vapor pressure transition metal precursors and high vapor pressure organochalcogen precursors are utilized.

Although FIG. 9 illustrate the use of argon, hydrogen, and oxygen gases that are blown through a standalone flow-controlled channel to the furnace 950, also referred to as a reaction chamber, other gases can be utilized as appropriate to the particular application. Within the quartz tube inside the furnace 950, a substrate 952 with a diameter up to 10 cm is placed upon a sapphire boat in the second zone of the furnace 950. In FIG. 9, the furnace is a three-zone furnace and the three zones are operated at temperatures of 600° C., 350° C., and 350° C., respectively, during the growth process. Thus, embodiments of the present invention provide the CMOS compatible MOCVD growth processes as illustrated by this growth process at 350° C.

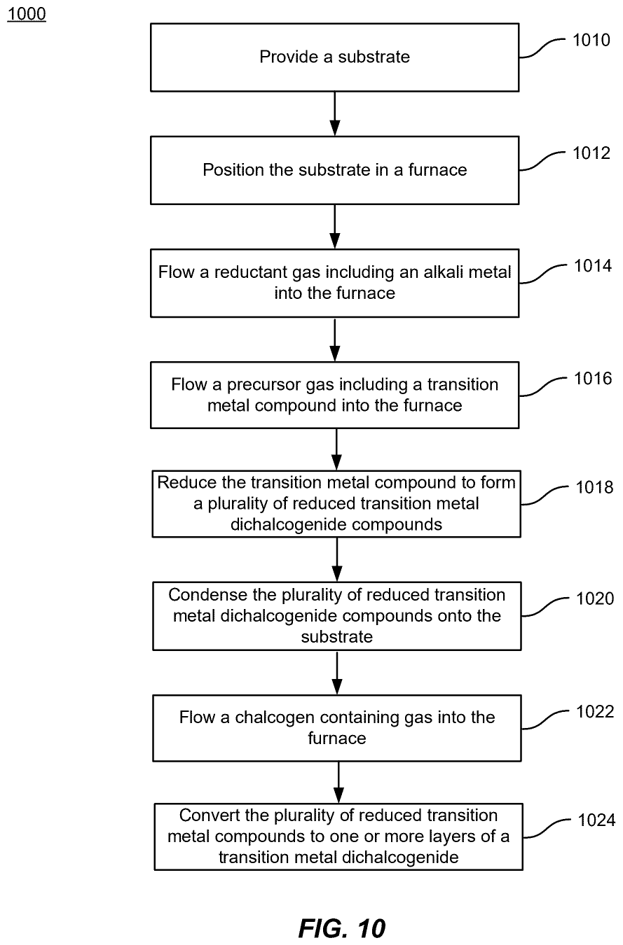

FIG. 10 is a simplified flowchart illustrating a method of growing a monolayer TMD by MOCVD according to an embodiment of the present invention. The method 1000 discussed in relation to FIG. 10 can be implemented using the MOCVD system shown in FIG. 9.

Referring to FIG. 10, the method 1000 includes providing a substrate (1010) and positioning the substrate in a furnace (1012). As an example, the substrate can be a silicon oxide substrate that is placed on a sapphire boat in the second zone of a three-zone furnace held at 10 torr with zones one, two, and three heated to 600° C., 350° C., and 350° C., respectively.

As described more fully below, in an MOCVD process using cesium as the alkali ion (i.e., the reductant gas), molybdenum pentachloride as the transition metal compound, and diethyl sulfide as the chalcogen precursor, cesium, molybdenum pentachloride, and diethyl sulfide are added to three unconnected bubblers held at temperatures of 90° C., 20° C., and 120° C., respectively, with the pressure in each bubbler (i.e., 750 torr) regulated by a mass flow controller and a needle valve in series for each bubbler.

The method 1000 also includes a nucleation stage that includes flowing a reductant gas including an alkali metal into the furnace (1014), flowing a precursor gas including a transition metal compound into the furnace (1016), and reducing the transition metal compound to produce a plurality of reduced transition metal compounds (1018). The nucleation stage also includes condensing the plurality of reduced transition metal compounds onto the substrate (1020). Each of the plurality of reduced transition metal compounds is electrostatically aligned to adjacent reduced transition metal compounds of the plurality of reduced transition metal compounds.

During an exemplary nucleation stage, 10 sccm of argon is piped through the bubbler for molybdenum pentachloride, 20 sccm of argon through the bubbler for cesium, and an auxiliary argon flow of 400 sccm is added to the reaction chamber (i.e., the furnace) through an alternate channel. The nucleation stage can have a duration of 1 hour although other time periods are included within the scope of the present invention. In this exemplary process, the alkali metal is cesium and the precursor gas including a transition metal is molybdenum pentachloride.

The method 1000 further includes a growth stage flowing a chalcogen containing gas into the furnace (1022) and converting the plurality of reduced transition metal compounds to one or more layers of a transition metal dichalcogenide (1024). The growth stage can have a duration of 1 hour although other time periods are included within the scope of the present invention.

Continuing with the exemplary process discussed above, during the growth stage, which can have a duration of 1 hour, although other time periods are included within the scope of the present invention, the flow rates through the cesium and molybdenum bubblers remain unchanged, while 100 sccm of argon is flown through the diethyl sulfide bubbler and 2 sccm of hydrogen is added to the auxiliary argon flow.

During a 20-minute cooldown stage, the furnace is allowed to cool to 300° C., the gas flux through the cesium and molybdenum bubblers is stopped, and the flows through remaining channels continued until the system attains atmospheric pressure.

It should be appreciated that the specific steps illustrated in FIG. 10 provide a particular method of growing a monolayer TMD by MOCVD according to an embodiment of the present invention. Other sequences of steps may also be performed according to alternative embodiments. For example, alternative embodiments of the present invention may perform the steps outlined above in a different order. Moreover, the individual steps illustrated in FIG. 10 may include multiple sub-steps that may be performed in various sequences as appropriate to the individual step. Furthermore, additional steps may be added or removed depending on the particular applications. One of ordinary skill in the art would recognize many variations, modifications, and alternatives.

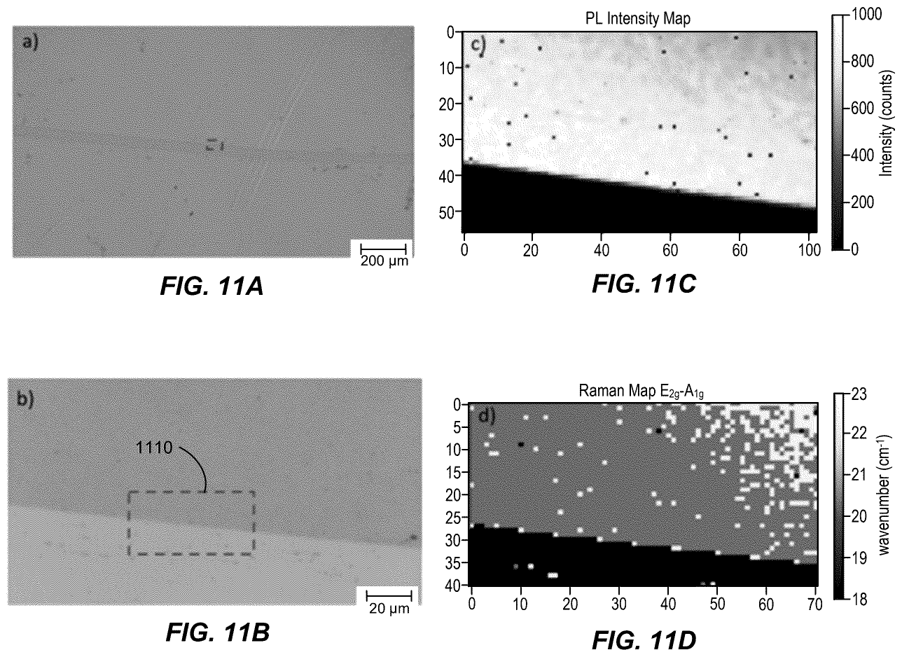

FIG. 11A is an optical microscope image of MOCVD-grown MoS₂ on a SiO₂ substrate at a first magnification according to an embodiment of the present invention. FIG. 11B is an optical microscope image of the MOCVD-grown MoS₂ shown in FIG. 11A at a second, higher magnification according to an embodiment of the present invention. In FIG. 11A, the scale bar has a dimension of 200 μm. In FIG. 11B, the scale bar has a dimension of 20 μm.

The MoS₂ illustrated in FIGS. 11A and 11B was grown at 350° C. using cesium as the reductant gas (i.e., the alkali metal precursor). As shown in FIGS. 11A and 11B, an extended monolayer film free of bulk structures is produced using embodiments of the present invention. The inventors believe that in accordance with the proposed mechanism of electron transfer and weak compensation, cesium, which has a low oxidation potential and weak electron screening, donates its valance electrons to the MoCl₅ precursor and induces alignment of the reduced transition metal precursor.

FIG. 11C is a photoluminescence intensity map of the region contained in the dashed box 1110 shown in FIG. 11B, which is taken with an excitation laser wavelength of 514 nm. As illustrated in the photoluminescence intensity map shown in FIG. 11C, which is obtained near the edge of the monolayer, the upper portion of the photoluminescence intensity map indicates the monolayer nature of the MoS₂. In contrast, the underlying substrate produces substantially no photoluminescence as would be expected.

FIG. 11D shows a map of the wavenumber difference between spectral peaks of the A_{1g} and E_{2g} modes in the Raman spectrum for the MoS₂ in the illustrated region. As illustrated by the data shown in FIG. 11D, which, like the photoluminescence intensity map shown in FIG. 11C, is obtained near the edge of the monolayer, the upper portion of the Raman map indicates the monolayer nature of the MoS₂. In contrast, the underlying substrate is clearly delineated.

In order to provide examples of both the CVD and MOCVD processes that can be utilized to form TMD monolayers, the following exemplary growth processes are provided by embodiments of the present invention.

CVD Synthesis of MoS₂ by Electrostatic Self-Assembly with CsI

In this embodiment, 15 mg of MoO₃ is admixed with 15 mg of CsI and the powder couched beneath a suspended (Si, SiO₂, sapphire) substrate in a ceramic boat. In a separate boat 15 inches upstream from the substrate, 150 mg of sulfur is heated in a low temperature region. After evacuating the system to 30 mTorr, the quartz tube is brought back to atmospheric pressure with an argon flux of 80 sccm, whereupon the furnace is heated to 785° C. in 35 minutes and kept at this temperature for 10 minutes. Simultaneously, the sulfur source is heated to 200° C. with a heating tape. After 10 minutes, the furnace is cooled to 400° C. without quenching. FIG. 6 shows the optical and spectroscopic characteristics of the material produced with this scheme on a sapphire substrate.

Optical microscopy images demonstrate that in accordance with the proposed mechanism of electron transfer and weak compensation, the alignment process is independent of the underlying substrate and produces comparable results across a broad range of substrates, including single crystal sizes on the order of 1 mm in lateral dimensions. Photoluminescence intensity maps and maps of the wavenumber difference between spectral peaks of the A_{1g} and E_{2g} modes in the Raman spectrum are consistent with the presence of the single crystal monolayer of MoS₂.

CVD Synthesis of MoS₂ by Electrostatic Self-Assembly with LiI

In this embodiment, 15 mg of MoO₃ is admixed with 5 mg of LiI and the powder couched beneath a suspended (Si, SiO₂, sapphire) substrate in a ceramic boat. In a separate boat 15 inches upstream from the substrate, 150 mg of sulfur is heated in a low temperature region. After evacuating the system to 30 mTorr, the quartz tube is brought back to atmospheric pressure with an argon flux of 80 sccm, whereupon the furnace is heated to 785° C. in 35 minutes and kept at this temperature for 10 minutes. Simultaneously, the sulfur source is heated to 200° C. with a heating tape. After 10 minutes, the furnace is cooled to 400° C. without quenching.

Optical microscopy images demonstrate that in accordance with the proposed mechanism of electron transfer and weak compensation, the alignment process is independent of the underlying substrate and produces comparable results across a broad range of substrates including single crystal sizes on the order of 300 μm. Photoluminescence intensity maps and maps of the wavenumber difference between spectral peaks of the A_{1g} and E_{2g} modes in the Raman spectrum are consistent with the presence of the single crystal monolayer of MoS₂.

CVD Synthesis of MoS₂ by Electrostatic Self-Assembly with KI

In this embodiment, 15 mg of MoO₃ is admixed with 10 mg of KI and the powder couched beneath a suspended (Si, SiO₂, sapphire) substrate in a ceramic boat. In a separate boat 15 inches upstream from the substrate, 150 mg of sulfur is heated in a low temperature region. After evacuating the system to 30 mTorr, the quartz tube is brought back to atmospheric pressure with an argon flux of 80 sccm, whereupon the furnace is heated to 785° C. in 35 minutes and kept at this temperature for 10 minutes. Simultaneously, the sulfur source is heated to 200° C. with a heating tape. After 10 minutes, the furnace is cooled to 400° C. without quenching.

CVD Synthesis of MoS₂ by Electrostatic Self-Assembly with CsC₅H₉O₂

In this embodiment, 15 mg of MoO₃ is admixed with 15 mg cesium pivalate and the powder couched beneath a suspended (Si, SiO₂, sapphire) substrate in a ceramic boat. In a separate boat 15 inches upstream from the substrate, 150 mg of sulfur is heated in a low temperature region. After evacuating the system to 30 mTorr, the quartz tube is brought back to atmospheric pressure with an argon flux of 80 sccm, whereupon the furnace is heated to 785° C. in 35 minutes and kept at this temperature for 10 minutes. Simultaneously, the sulfur source is heated to 200° C. with a heating tape. After 10 minutes, the furnace is cooled to 400° C. without quenching.

Optical microscopy images of MoS₂ on silicon dioxide grown with the addition of Cesium pivalate indicate that in accordance with the proposed mechanism of electron transfer and weak compensation, the alignment process proceeds by weak electron transfer from the pivalate ion to the molybdenum precursor. Photoluminescence intensity maps and maps of the wavenumber difference between the spectral peaks of the A_{1g} and E_{2g} modes in the Raman spectrum are consistent with the presence of the single crystal monolayer of MoS₂.

CVD Synthesis of MoS₂ by Electrostatic Self-Assembly with CsOH·H₂O

15 mg of MoO₃ is admixed with 10 mg CsOH·H₂O and the powder couched beneath a suspended (Si, SiO₂, sapphire) substrate in a ceramic boat. In a separate boat 15 inches upstream from the substrate, 150 mg of sulfur is heated in a low temperature region. After evacuating the system to 30 mTorr, the quartz tube is brought back to atmospheric pressure with an argon flux of 80 sccm, whereupon the furnace is heated to 785° C. in 35 minutes and kept at this temperature for 10 minutes. Simultaneously, the sulfur source is heated to 200° C. with a heating tape. After 10 minutes, the furnace is cooled to 400° C. without quenching.

Optical microscopy images of MoS₂ on silicon dioxide grown with the addition of Cesium hydroxide indicate that in accordance with the proposed mechanism of electron transfer and weak compensation, the alignment process proceeds by weak electron transfer from the hydroxide ion to the molybdenum precursor. Photoluminescence intensity maps and maps of the wavenumber difference between the spectral peaks of the A_{1g} and E_{2g} modes in the Raman spectrum are consistent with the presence of the single crystal monolayer of MoS₂.

CVD Synthesis of MoSe₂ by Electrostatic Self-Assembly with CsI

15 mg of MoO₃ is admixed with 15 mg of CsI and the powder couched beneath a suspended (Si, SiO₂, sapphire) substrate in a ceramic boat. In a separate boat 15 inches upstream from the substrate, 150 mg of selenium is heated in a low temperature region. After evacuating the system to 30 mTorr, the quartz tube is brought back to atmospheric pressure with an argon flux of 80 sccm, whereupon the furnace is heated to 785° C. in 35 minutes and kept at this temperature for 10 minutes. Simultaneously, the selenium source is heated to 300° C. with a heating tape and a hydrogen flux of 10 sccm is added to the system. After 10 minutes, the furnace is cooled to 400° C. without quenching.

Optical microscopy images of MoSe₂ on sapphire grown with the addition of CsI indicate that in accordance with the proposed mechanism of electron transfer and weak compensation, the alignment process is independent of the underlying substrate and produces comparable results across a broad range of substrates (single crystal sizes on the order of 1 mm). Photoluminescence intensity maps and maps of the wavenumber difference between peaks A_{1g} and E_{2g} of the Raman spectrum are consistent with the presence of the single crystal monolayer of MoSe₂.

CVD Synthesis of MoSe₂ by Electrostatic Self-Assembly with KI

15 mg of MoO₃ is admixed with 10 mg of KI and the powder couched beneath a suspended (Si, SiO₂, sapphire) substrate in a ceramic boat. In a separate boat 15 inches upstream from the substrate, 150 mg of selenium is heated in a low temperature region. After evacuating the system to 30 mTorr, the quartz tube is brought back to atmospheric pressure with an argon flux of 80 sccm, whereupon the furnace is heated to 785° C. in 35 minutes and kept at this temperature for 10 minutes. Simultaneously, the selenium source is heated to 300° C. with a heating tape and a hydrogen flux of 10 sccm is added to the system. After 10 minutes, the furnace is cooled to 400° C. without quenching.

Optical microscopy images of MoSe₂ on sapphire grown with the addition of KI indicate that in accordance with the proposed mechanism of electron transfer and weak compensation, the alignment process is independent of the underlying substrate and produces comparable results across a broad range of substrates (single crystal sizes on the order of 300 μm). Photoluminescence intensity maps and maps of the wavenumber difference between the spectral peaks of the A_{1g} and E_{2g} modes in the Raman spectrum are consistent with the presence of the single crystal monolayer of MoSe₂.

CVD Synthesis of WSe₂ by Electrostatic Self-Assembly with CsI

15 mg of WO₃ is admixed with 15 mg of CsI and the powder couched beneath a suspended (Si, SiO₂, sapphire) substrate in a ceramic boat. In a separate boat 15 inches upstream from the substrate, 150 mg of selenium is heated in a low temperature region. After evacuating the system to 30 mTorr, the quartz tube is brought back to atmospheric pressure with an argon flux of 80 sccm, whereupon the furnace is heated to 850° C. in 35 minutes and kept at this temperature for 10 minutes. Simultaneously, the selenium source is heated to 300° C. with a heating tape and a hydrogen flux of 10 sccm is added to the system. After 10 minutes, the furnace is cooled to 400° C. without quenching.

Optical microscopy images of WSe₂ on sapphire grown with the addition of CsI indicate that in accordance with the proposed mechanism of electron transfer and weak compensation, the alignment process is independent of the underlying substrate and produces comparable results across a broad range of substrates (single crystal sizes on the order of 1 μm). Photoluminescence intensity maps and maps of the wavenumber difference between the spectral peaks of the A_{1g} and E_{2g} modes in the Raman spectrum are consistent with the presence of the single crystal monolayer of WSe₂.

CVD Synthesis of MoS₂ by Electrostatic Self-Assembly with N(Me)₄I

15 mg of MoO₃ is admixed with 15 mg of N(Me)₄I and the powder couched beneath a suspended (Si, SiO₂, sapphire) substrate in a ceramic boat. In a separate boat 15 inches upstream from the substrate, 150 mg of sulfur is heated in a low temperature region. After evacuating the system to 30 mTorr, the quartz tube is brought back to atmospheric pressure with an argon flux of 80 sccm, whereupon the furnace is heated to 785° C. in 35 minutes and kept at this temperature for 10 minutes. Simultaneously, the sulfur source is heated to 200° C. with a heating tape. After 10 minutes, the furnace is cooled to 400° C. without quenching.

Optical microscopy images of MoS₂ grown with the addition of N(Me)₄I demonstrate local alignment and ordered structures on a silicon oxide substrate. In accordance with the proposed mechanism of electron transfer and weak compensation, the iodide ion donates electrons to the Mo precursor, screened by a quaternary ammonium ion (known to mimic alkali ions) and induces ordering at sufficiently high temperatures, indicating that a metal ion is not required to produce ordered structures. Photoluminescence intensity maps and maps of the wavenumber difference between the spectral peaks of the A_{1g} and E_{2g} modes in the Raman spectrum are consistent with the presence of the single crystal monolayer of MoS₂.

CVD Synthesis of MoS₂ by Electrostatic Self-Assembly with N(Bu)₄ (BH₄)

15 mg of MoO₃ is admixed with 35 mg of N(bu)₄(BH₄) and the powder couched beneath a suspended (Si, SiO₂, sapphire) substrate in a ceramic boat. In a separate boat 15 inches upstream from the substrate, 150 mg of sulfur is heated in a low temperature region. After evacuating the system to 30 mTorr, the quartz tube is brought back to atmospheric pressure with an argon flux of 80 sccm, whereupon the furnace is heated to 785° C. in 35 minutes and kept at this temperature for 10 minutes. Simultaneously, the sulfur source is heated to 200° C. with a heating tape. After 10 minutes, the furnace is cooled to 400° C. without quenching.

Optical microscopy images of MoS₂ grown with the addition of N(bu)₄(BH₄) demonstrate local alignment and ordered structures on a silicon oxide substrate. It should be noted that in this embodiment, a salt bearing no alkali ion nor iodide is used to orchestrate Columbic unbalancing, furnishing only a charge donor (borohydride) and a stable cation that mimics the alkali metals to operate. Photoluminescence intensity maps and maps of the wavenumber difference between the spectral peaks of the A_{1g} and E_{2g} modes in the Raman spectrum are consistent with the presence of the single crystal monolayer of MoS₂.

CVD Synthesis of MoS₂ by Electrostatic Self-Assembly with Ag

15 mg of MoO₃ is admixed with 30 mg of Ag₂O (Ag₂O decomposes to Ag metal at 405° C.) and the powder couched beneath a suspended (Si, SiO₂, sapphire) substrate in a ceramic boat. In a separate boat 15 inches upstream from the substrate, 150 mg of sulfur is heated in a low temperature region. After evacuating the system to 30 mTorr, the quartz tube is brought back to atmospheric pressure with an argon flux of 80 sccm, whereupon the furnace is heated to 785° C. in 35 minutes and kept at this temperature for 10 minutes. Simultaneously, the sulfur source is heated to 200° C. with a heating tape. After 10 minutes, the furnace is cooled to 400° C. without quenching.

Optical microscopy images of MoS₂ grown with the addition of silver metal indicate that in accordance with the proposed mechanism of electron transfer and weak compensation, though silver may be a noble metal, it can weakly donate its lone 4 s electron to the molybdenum precursor, which is confirmed by the color MoO₃'s color change to black at 750° C., which betrays the activation of the d-d transition in molybdenum's crystal field split d orbitals, and induce weak local alignment (on a scale less than 10 μm). Photoluminescence intensity maps and maps of the wavenumber difference between the spectral peaks of the A_{1g} and E_{2g} modes in the Raman spectrum are consistent with the presence of the single crystal monolayer of MoS₂.

CVD Synthesis of MoS₂ by Electrostatic Self-Assembly with Al

15 mg of MoO₃ is admixed with 30 mg of Al and the powder couched beneath a suspended (Si, SiO₂, sapphire) substrate in a ceramic boat. In a separate boat 15 inches upstream from the substrate, 150 mg of sulfur is heated in a low temperature region. After evacuating the system to 30 mTorr, the quartz tube is brought back to atmospheric pressure with an argon flux of 80 sccm, whereupon the furnace is heated to 785° C. in 35 minutes and kept at this temperature for 10 minutes. Simultaneously, the sulfur source is heated to 200° C. with a heating tape. After 10 minutes, the furnace is cooled to 400° C. without quenching.

Optical microscopy images of MoS₂ grown with the addition of aluminum metal indicate that in accordance with the proposed mechanism of electron transfer and weak compensation, aluminum, which has a relatively high oxidation potential, will donate its three valance electrons to the Mo precursor at 450° C. and induce weak local alignment, albeit stronger than silver by dint of the greater extent of charge transfer (though still no greater than 50 μm in some embodiments). Photoluminescence intensity maps and maps of the wavenumber difference between the spectral peaks of the A_{1g} and E_{2g} modes in the Raman spectrum are consistent with the presence of the single crystal monolayer of MoS₂.

CVD Synthesis of MoS₂ by Electrostatic Self-Assembly with Th

15 mg of MoO₃ is admixed with 15 mg of Th and the powder couched beneath a suspended (Si, SiO₂, sapphire) substrate in a ceramic boat. In a separate boat 15 inches upstream from the substrate, 150 mg of sulfur is heated in a low temperature region. After evacuating the system to 30 mTorr, the quartz tube is brought back to atmospheric pressure with an argon flux of 80 sccm, whereupon the furnace is heated to 785° C. in 35 minutes and kept at this temperature for 10 minutes. Simultaneously, the sulfur source is heated to 200° C. with a heating tape. After 10 minutes, the furnace is cooled to 400° C. without quenching.

Optical microscopy images of MoS₂ grown with the addition of thorium (a weakly radioactive) metal, show the alignment of bilayer structures within single crystal grains, consistent with the coalescence mechanism discussed in relation to FIG. 1F. In accordance with the proposed mechanism of electron transfer and weak compensation, thorium, which has a high oxidation potential and strong electron screening, will donate its valance electrons to the Mo precursor and induce weak local alignment at sufficiently high temperatures. Photoluminescence intensity maps and maps of the wavenumber difference between the spectral peaks of the A_{1g} and E_{2g} modes in the Raman spectrum are consistent with the presence of bilayer structures aligning within the single crystal domains of MoS₂.

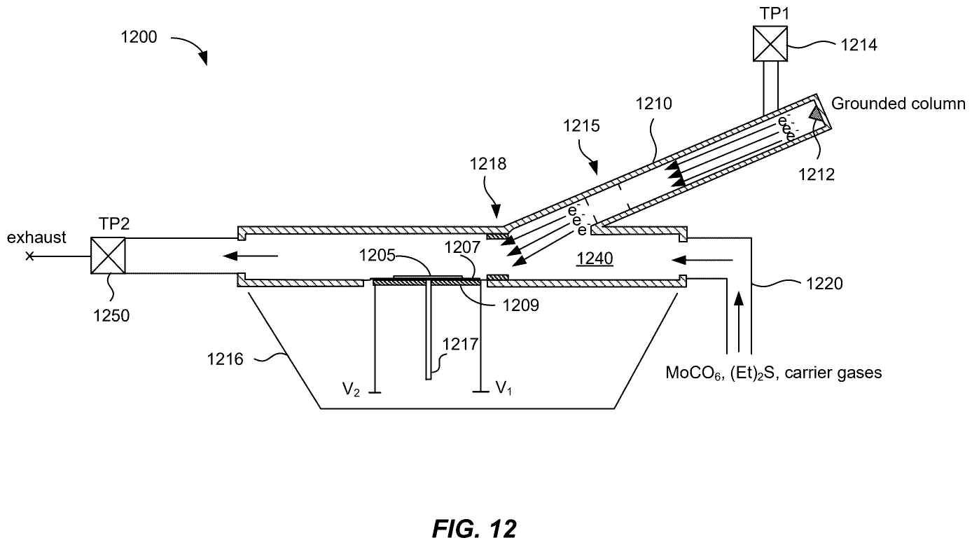

FIG. 12 is a simplified schematic diagram illustrating an alternative MOCVD system for synthesis of 2D-TMD materials by electrostatic self-assembly according to an embodiment of the present invention. As discussed more fully below, the system illustrated in FIG. 12 enables growth of TMDs by the utilization of an electron beam to reduce the transition metal compound in the absence of reductant gases, for example, an alkali metal.

Referring to FIG. 12, the MOCVD system 1200 includes a grounded column 1210 that includes a tungsten filament 1212 electrically connected to an anode. The grounded column 1210 is evacuated using a first turbo pump 1214 and supports the generation and transport of electrons as illustrated. The grounded column 1210 is in fluid communication with a reaction volume 1240 of a grounded steel reaction chamber 1216 that includes a sample stage 1207 configured to support a substrate 1205. In the illustrated embodiment, the sample stage 1207 is fabricated from steel, and is supported on a graphite susceptor with an induction heater 1209. In order to direct and control the flow of electrons produced in the grounded column 1210, deflection and stigmatization optics 1215 are positioned along the grounded column 1210 as illustrated. An annular insulated RF heater 1218 is positioned at the exit of the grounded column 1210 upstream of the substrate 1205.

Process gases are provided from gas source 1220 in fluid communication with the reaction volume 1240, which is exhausted using a second turbo pump 1250. In the illustrated embodiment, the process gases are MoCO₆, (Et)₂S, and carrier gases.

During operation, an electron beam is produced by the tungsten filament 1212 of the grounded column 1210. The electron beam is accelerated along the grounded column 1210 and after collimating the electron beam by the deflection and stigmatization optics 1215, also referred to as electrostatic collimation optics, the electron beam enters the reaction volume 1240 in the vicinity of the annular insulated RF heater 1218. The application of voltages to the sample stage 1217 using voltage sources V₁ and V₂ (V₁≠V₂) produces a voltage gradient and therefore a directed electric field across the substrate 1205 to assist the self-assembly of negatively charged precursors. Additionally, at least one of the voltages must be negative and the other may be either negative or grounded to ensure that the negative charge in the reduced precursor material is not neutralized during the growth process by the external voltage sources.

Process gases, including a transition metal precursor and a chalcogenide containing gas enter the reaction volume 1240. The transition metal precursor is reduced as it flows through the electron beam, producing a plurality of reduced transition metal compounds. Additionally, the chalcogenide containing gas is heated as it passes through the annular insulated RF heater 1218, resulting in production of a reactive chalcogenide. The plurality of reduced transition metal compounds electrostatically align as they condense on the substrate and are then reacted with the chalcogen to form one or more layers of a transition metal dichalcogenide on the substrate.

Thus, in the embodiment illustrated in FIG. 12, in comparison with the MOCVD system 900 illustrated in FIG. 9, no alkali metal is utilized to reduce the transition metal precursor since the transition metal precursor is reduced by the interaction with the electron beam.

Various examples of the present disclosure are provided below. As used below, any reference to a series of examples is to be understood as a reference to each of those examples disjunctively (e.g., “Examples 1-4” is to be understood as “Examples 1, 2, 3, or 4”).

Example 1 is a method of growing a transition metal dichalcogenide, the method comprising: providing a substrate; positioning the substrate in a furnace; reducing a transition metal compound to produce a plurality of reduced transition metal compounds, wherein the plurality of reduced transition metal compounds is electrostatically aligned on the substrate; and reacting the plurality of reduced transition metal compounds with a chalcogen precursor to form one or more layers of a transition metal dichalcogenide.

Example 2 is a method of example 1 wherein the substrate has an area greater than 1 cm² and the one or more layers of the transition metal dichalcogenide comprise fully connected monolayer transition metal dichalcogenides with a grain size greater than 1 mm.

Example 3 is the method of example(s) 1-2 wherein formation of the one or more layers of the transition metal dichalcogenide is independent of the transition metal compound and the chalcogen precursor.

Example 4 is the method of example(s) 1-3 wherein the substrate is electrically insulating or semiconducting and formation of the one or more layers of the transition metal dichalcogenide is independent of the substrate.

Example 5 is the method of example(s) 1-4 wherein the one or more layers of the transition metal dichalcogenide consists of a monolayer.

Example 6 is the method of example(s) 1-5 wherein the substrate is electrically insulating or semiconducting.

Example 7 is the method of example(s) 1-6 wherein the substrate is amorphous.

Example 8 is the method of example(s) 1-7 wherein the substrate comprise SiO₂.

Example 9 is the method of example(s) 1-8 wherein the substrate comprises a single crystal sapphire substrate.

Example 10 is the method of example(s) 1-9 wherein reducing the transition metal compound to produce the plurality of reduced transition metal compounds comprises introducing a reductant gas including a halogen into the furnace.

Example 11 is the method of example(s) 1-10 wherein the reductant gas comprises CsI, KI, or LiI.

Example 12 is the method of example(s) 1-11 wherein the transition metal compound comprises MoO₃ or MoCl₅.

Example 13 is the method of example(s) 1-12 wherein the plurality of reduced transition metal compounds are characterized by a charge state.

Example 14 is the method of example(s) 1-13 wherein the charge state is a negative charge state.

Example 15 is the method of example(s) 1-14 wherein a temperature of the furnace while condensing the plurality of reduced transition metal compounds onto the substrate is less than 450° C.

Example 16 is the method of example(s) 1-15 wherein each of the plurality of reduced transition metal compounds are electrostatically aligned by a self-assembly process.

Example 17 is the method of example(s) 1-16 wherein the chalcogen precursor comprises sulfur or selenium.

Example 18 is a method of growing a transition metal dichalcogenide, the method comprising: providing a substrate; positioning the substrate in a furnace; flowing a reductant gas including an alkali metal into the furnace; flowing a precursor gas including a transition metal into the furnace; reducing the transition metal to produce a plurality of reduced transition metal compounds; condensing the plurality of reduced transition metal compounds onto the substrate, wherein each of the plurality of reduced transition metal compounds is electrostatically aligned to adjacent reduced transition metal compounds of the plurality of reduced transition metal compounds; flowing a chalcogen containing gas into the furnace; and converting the plurality of reduced transition metal compounds to one or more layers of a transition metal dichalcogenide.

Example 19 is the method of example 18 wherein the substrate is electrically insulating or semiconducting.

Example 20 is the method of example(s) 18-19 wherein the substrate is amorphous.

Example 21 is the method of example(s) 18-20 wherein the substrate comprise SiO₂.

Example 22 is the method of example(s) 18-21 wherein the reductant gas further includes a halogen.

Example 23 is the method of example(s) 18-22 wherein the reductant gas comprises CsI.

Example 24 is the method of example(s) 18-23 wherein the precursor gas including a transition metal comprises MoO₃ or MoCl₅.

Example 25 is the method of example(s) 18-24 wherein the plurality of reduced transition metal compounds are characterized by a charge state.

Example 26 is the method of example(s) 18-25 wherein the charge state is a negative charge state.

Example 27 is the method of example(s) 18-26 wherein a temperature of the furnace while condensing the plurality of reduced transition metal compounds onto the substrate is less than 450° C.

Example 28 is the method of example(s) 18-27 wherein each of the plurality of reduced transition metal compounds are electrostatically aligned by a self-assembly process.

Example 29 is the method of example(s) 18-28 wherein a temperature of the furnace while converting the plurality of reduced transition metal compounds to one or more layers of a transition metal dichalcogenide is less than 450° C.

Example 30 is the method of example(s) 18-29 wherein the chalcogen containing gas comprises sulfur.

Example 31 is the method of example(s) 18-30 wherein the one or more layers consists of a monolayer.

Example 32 is the method of example(s) 18-31 wherein: the substrate comprises SiO₂; the reductant gas comprises CsI; the precursor gas including a transition metal comprises MoO₃; the plurality of reduced transition metal compounds comprise Cs^{+x}Mo^{+6-x}O₃; the chalcogen containing gas comprises sulfur; and the transition metal dichalcogenide comprises MoS₂.

It is also understood that the examples and embodiments described herein are for illustrative purposes only and that various modifications or changes in light thereof will be suggested to persons skilled in the art and are to be included within the spirit and purview of this application and scope of the appended claims.

What is claimed is:

1. A method of growing a transition metal dichalcogenide, the method comprising:
providing a substrate;
positioning the substrate in a furnace;
reducing a transition metal compound to produce a plurality of reduced transition metal compounds, wherein the plurality of reduced transition metal compounds is electrostatically aligned on the substrate; and
reacting the plurality of reduced transition metal compounds with a chalcogen precursor to form one or more layers of a transition metal dichalcogenide.

2. The method of claim 1 wherein the substrate has an area greater than 1 cm² and the one or more layers of the transition metal dichalcogenide comprise fully connected monolayer transition metal dichalcogenides with a grain size greater than 1 mm.

3. The method of claim 1 wherein formation of the one or more layers of the transition metal dichalcogenide is independent of the transition metal compound and the chalcogen precursor.

4. The method of claim 3 wherein the substrate is electrically insulating or semiconducting and formation of the one or more layers of the transition metal dichalcogenide is independent of the substrate.

5. The method of claim 1 wherein the one or more layers of the transition metal dichalcogenide consists of a monolayer.

6. The method of claim 1 wherein the substrate is electrically insulating or semiconducting.

7. The method of claim 1 wherein the substrate is amorphous.

8. The method of claim 7 wherein the substrate comprise SiO₂.

9. The method of claim 1 wherein the substrate comprises a single crystal sapphire substrate.

10. The method of claim 1 wherein reducing the transition metal compound to produce the plurality of reduced transition metal compounds comprises introducing a reductant gas including a halogen into the furnace.

11. The method of claim 10 wherein the reductant gas comprises CsI, KI, or LiI.

12. The method of claim 1 wherein the transition metal compound comprises MoO₃ or MoCl₅.

13. The method of claim 1 wherein the plurality of reduced transition metal compounds are characterized by a charge state.

14. The method of claim 13 wherein the charge state is a negative charge state.

15. The method of claim 1 wherein a temperature of the furnace while condensing the plurality of reduced transition metal compounds onto the substrate is less than 450° C.

16. The method of claim 1 wherein each of the plurality of reduced transition metal compounds are electrostatically aligned by a self-assembly process.

17. The method of claim 1 wherein the chalcogen precursor comprises sulfur or selenium.

18. A method of growing a transition metal dichalcogenide, the method comprising:
providing a substrate;
positioning the substrate in a furnace;
flowing a reductant gas including an alkali metal into the furnace;
flowing a precursor gas including a transition metal into the furnace;
reducing the transition metal to produce a plurality of reduced transition metal compounds;
condensing the plurality of reduced transition metal compounds onto the substrate, wherein each of the plurality of reduced transition metal compounds is electrostatically aligned to adjacent reduced transition metal compounds of the plurality of reduced transition metal compounds;
flowing a chalcogen containing gas into the furnace; and
converting the plurality of reduced transition metal compounds to one or more layers of a transition metal dichalcogenide.

19. The method of claim 18 wherein a temperature of the furnace while converting the plurality of reduced transition metal compounds to one or more layers of a transition metal dichalcogenide is less than 450° C.

20. The method of claim 18 wherein:
the substrate comprises SiO₂;
the reductant gas comprises CsI;
the precursor gas including a transition metal comprises MoO₃;
the plurality of reduced transition metal compounds comprise Cs^{+x}Mo^{+6-x}O₃;
the chalcogen containing gas comprises sulfur; and
the transition metal dichalcogenide comprises MoS₂.
